(19) United States
(12) Patent Application Publication
(10) Pub. No.: US 2024/0015906 A1
(43) Pub. Date: Jan. 11, 2024

(54) ELECTRONIC DEVICE

(71) Applicant: Samsung Display Co., Ltd., Yongin-si (KR)

(72) Inventors: HONGKWAN LEE, Yongin-si (KR); YONGHYUCK LEE, Yongin-si (KR); HYUNJUN CHO, Yongin-si (KR); SOHRA HAN, Yongin-si (KR)

(21) Appl. No.: 18/212,643

(22) Filed: Jun. 21, 2023

(30) Foreign Application Priority Data
Jul. 7, 2022 (KR) 10-2022-0084017

(51) Int. Cl. H05K 5/02; D03D 1/00; D03D 15/267; C03C 25/1095; C03C 25/30; C03C 25/325; C03C 25/323; C03C 25/328; C03C 25/36; C03C 25/42

(52) U.S. Cl. CPC H05K 5/0217; D03D 1/00; D03D 15/267; C03C 25/1095; C03C 25/30; C03C 25/325; C03C 25/323; C03C 25/328; C03C 25/36; C03C 25/42; D10B 2401/061

(57) ABSTRACT

An electronic device includes a display panel including a folding region to fold with respect to a folding axis, and a non-folding region including a first non-folding region and a second non-folding region spaced apart with the folding region therebetween, and a support plate including a plurality of fiber layers including a plurality of reinforced fibers, the support plate being under the display panel, wherein the support plate has a thickness of about 100 μm to about 300 μm, when the thickness of the support plate is about 100 μm to about 200 μm, each fiber layer has a thickness of equal to or greater than about 30 μm and less than about 50 μm, and when the thickness is greater than about 200 μm and equal to or smaller than about 300 μm, each fiber layer has a thickness of about 40 μm to about 100 μm.

### CROSS-REFERENCE TO RELATED APPLICATIONS

This application claims priority to and the benefit of Korean Patent Application No. 10-2022-0084017, filed on Jul. 7, 2022, in the Korean Intellectual Property Office, the entire content of which is hereby incorporated by reference.

### BACKGROUND

### 1. Field

Embodiments of the present disclosure relate to an electronic device, and for example, to a foldable electronic device.

### 2. Description of Related Art

To provide image information, various electronic devices such as televisions, mobile phones, tablet computers, navigation systems, or game consoles are being utilized. Recently, with the technological development of electronic devices, various flexible electronic devices, which include a flexible display panel and are deformable to a curved shape, foldable, or rollable, are being developed. A flexible electronic device of which the shape is variously deformable may be easily carried, and may improve user convenience.

Such a flexible electronic device may require a support member for supporting a display panel without hindering a folding or bending operation, and it is desired or necessary to develop lightweight support members without lowering mechanical properties so as to improve user convenience.

### SUMMARY

Aspects of one or more embodiments of the present disclosure are directed toward an electronic device with improved display quality.

Additional aspects will be set forth in part in the description which follows and, in part, will be apparent from the description, or may be learned by practice of the presented embodiments of the disclosure.

One or more embodiments of the present disclosure provide an electronic device including a display panel including a folding region to fold with respect to a folding axis extending in one direction, and a non-folding region including a first non-folding region and a second non-folding region spaced apart from (separated from) each other with the folding region therebetween, and a support plate including a plurality of fiber layers including a plurality of reinforced fibers, the support plate being under the display panel, wherein the support plate has a thickness of about 100 μm to about 300 μm, when the thickness of the support plate is about 100 μm to about 200 μm, each fiber layer of the plurality of the fiber layers has a thickness of equal to or greater than about 30 μm and less than about 50 μm, and when the thickness of the support plate is greater than about 200 μm and equal to or smaller than about 300 μm, each fiber layer of the plurality of fiber layers has a thickness of about 40 μm to about 100 μm.

In one or more embodiments, each reinforced fiber of the plurality of reinforced fibers may include a glass fiber.

In one or more embodiments, each fiber layer of the plurality of fiber layers may have a woven shape in which reinforced fibers of the plurality of reinforced fibers are arranged alternately.

In one or more embodiments, the support plate may further include a matrix part including a polymer resin, and the plurality of fiber layers are inside the matrix part.

In one or more embodiments, the support plate may further include inorganic particles dispersed in the matrix part.

In one or more embodiments, the matrix part may include at least one of an epoxy-based resin, a polyester-based resin, a polyimide-based resin, a polycarbonate-based resin, a polypropylene-based resin, a polybutylene-based resin, or a vinyl ester-based resin.

In one or more embodiments, the support plate may have a flexural modulus of about 10 GPa to about 35 GPa.

In one or more embodiments, each fiber layer of the plurality of fiber layers may have the same thickness.

In one or more embodiments, fibers layers of the plurality of fiber layers may have thicknesses different from each other. In this case, fiber layers of the plurality of fiber layers on an outermost region of the support plate may be thinner than a fiber layer (or layers) of the plurality of fiber layers inside the support plate. For example, the fiber layers of the plurality of fiber layers on the outermost region of the support plate may be thinner on average than the fiber layers of the plurality of fiber layers inside the support plate.

In one or more embodiments, the support plate may include a plurality of sub-plates stacked in a thickness direction, and each sub-plate of the plurality of sub-plates may include at least one of the plurality of fiber layers.

In one or more embodiments, a total number of sub-plates of the plurality of sub-plates in the support plate is three to five.

In one or more embodiments, the support plate may include a folding part corresponding to the folding region, and having a plurality of openings, a first plate non-folding part corresponding to the first non-folding region, and a second plate non-folding part corresponding to the second non-folding region.

In one or more embodiments, the plurality of openings may include a plurality of first openings and a plurality of second openings arranged in a staggered manner in a first direction.

In one or more embodiments, the support plate may include a first plate overlapping the first non-folding region, and a second plate overlapping the second non-folding region, and spaced apart from the first plate.

In one or more embodiments, the plurality of reinforced fibers may be about 48 wt % to about 52 wt % with respect to a total weight of the plurality of sub-plates.

In one or more embodiments, the electronic device may further include a hard coat layer on top of and/or under the support plate.

In one or more embodiments, the hard coat layer may have a thickness of about 1 μm to about 20 μm.

In one or more embodiments of the present disclosure, an electronic device having a folding region to fold with respect to a folding axis extending in one direction, and a non-folding region adjacent to the folding region, the electronic device includes a display module, and a support plate including a matrix part (e.g., a matrix), and a plurality of fiber layers inside the matrix part, the support plate being under the display module, wherein the support plate includes a plurality of sub-plates stacked in a thickness direction, each sub-plate of the plurality of sub-plates includes a fiber layer of the plurality of fiber layers having a thickness proportional to a thickness of the support plate, and the plurality of fiber layers include glass fibers having a woven shape in which fibers are arranged alternately.

### BRIEF DESCRIPTION OF THE DRAWINGS

The accompanying drawings are included to provide a further understanding of embodiments of the present disclosure, and are incorporated in and constitute a part of this specification. The drawings illustrate embodiments of the present disclosure and, together with the description, serve to explain principles of the present disclosure. In the drawings:

FIG. 1A is a perspective view illustrating an unfolded state of an electronic device according to one or more embodiments of the present disclosure;

FIG. 1B is a perspective view illustrating a folding operation state of an electronic device according to one or more embodiments of the present disclosure;

FIG. 1C is a perspective view illustrating a folding operation state of an electronic device according to one or more embodiments of the present disclosure;

FIG. 1D is a perspective view illustrating a folded state of an electronic device according to one or more embodiments of the present disclosure;

FIG. 1E is a perspective view illustrating a folded state of an electronic device according to one or more embodiments of the present disclosure;

FIG. 2 is an exploded perspective view of an electronic device according to one or more embodiments of the present disclosure;

FIGS. 3A and 3B are each a cross-sectional view of an electronic device taken along line I-I′ of FIG. 2, according to embodiments of the present disclosure;

FIGS. 4A and 4B are each a cross-sectional view of a support part according to embodiments of the present disclosure;

FIG. 5 is a perspective view of a support plate according to one or more embodiments of the present disclosure;

FIG. 6 is a plan view of region AA of the support plate of FIG. 5, according to one or more embodiments of the present disclosure;

FIG. 7 is a perspective view of region BB of the support plate of FIG. 5, according to one or more embodiments of the present disclosure;

FIGS. 8A-8D are each an enlarged cross-sectional view of a support plate taken along line II-II′ of FIG. 7, according to embodiments of the present disclosure;

FIGS. 8E and 8F are each a graph showing the lattice visibility and properties of a support plate according to one or more embodiments of the present disclosure; and

FIG. 9 is a cross-sectional view of an electronic device according to one or more embodiments of the present disclosure.

### DETAILED DESCRIPTION

The present disclosure may be modified in many alternate forms, and thus specific embodiments will be illustrated in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

In the present disclosure, “directly disposed” means that there is no layer, film, region, plate, etc. added between a portion such as a layer, film, region, or plate and another portion. For example, “directly disposed” means that two layers or two members are disposed without utilizing an additional member such as an adhesive member therebetween.

Unless otherwise noted, like reference numerals denote like elements throughout the attached drawings and the written description, and thus, descriptions thereof may not be repeated. In the drawings, thicknesses, ratios, and dimensions of components may be exaggerated for effective description of technical content and/or clarity. As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

Spatially relative terms, such as “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries should be interpreted as having a meaning consistent with the meaning in the context of the relevant art and/or the present disclosure, and should not be interpreted in an idealized or overly formal sense, unless explicitly so defined herein.

Terms such as comprise, “include,” or “have” when used in this disclosure, specify the presence of the stated features, integers, steps, operations, elements, parts and/or components, but do not preclude the presence or addition of one or more other features, integers, steps, operations, elements, parts, components, and/or combinations thereof.

Expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

Hereinafter, an electronic device according to one or more embodiments of the present disclosure will be described with reference to the drawings.

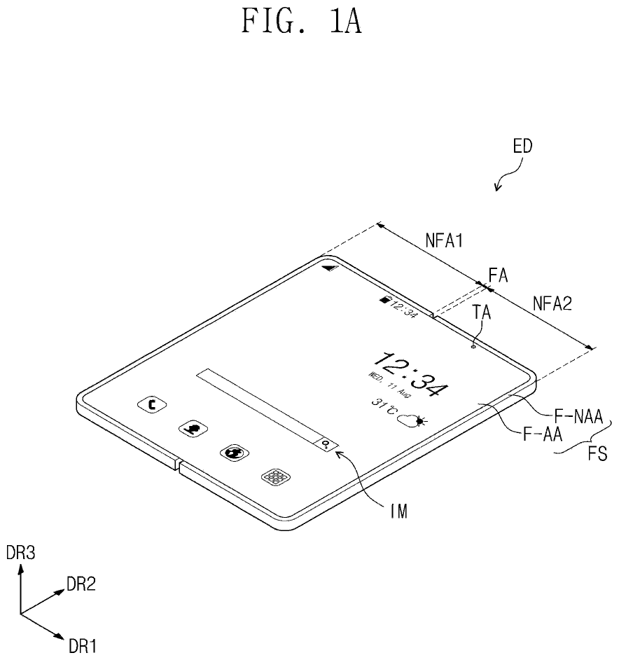

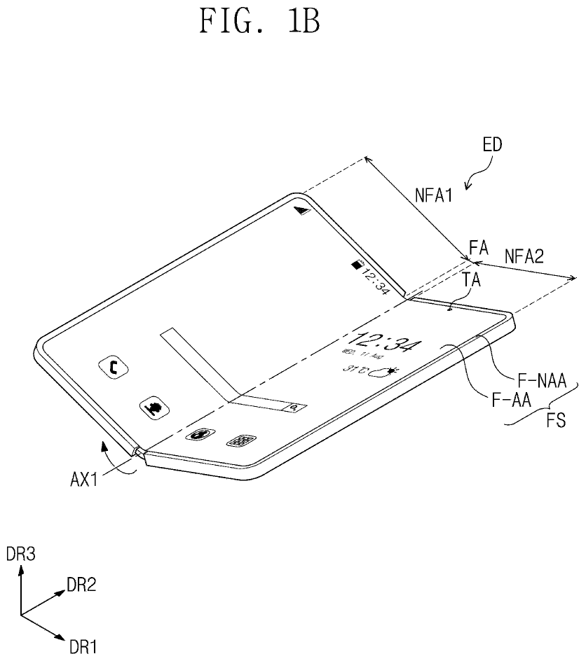

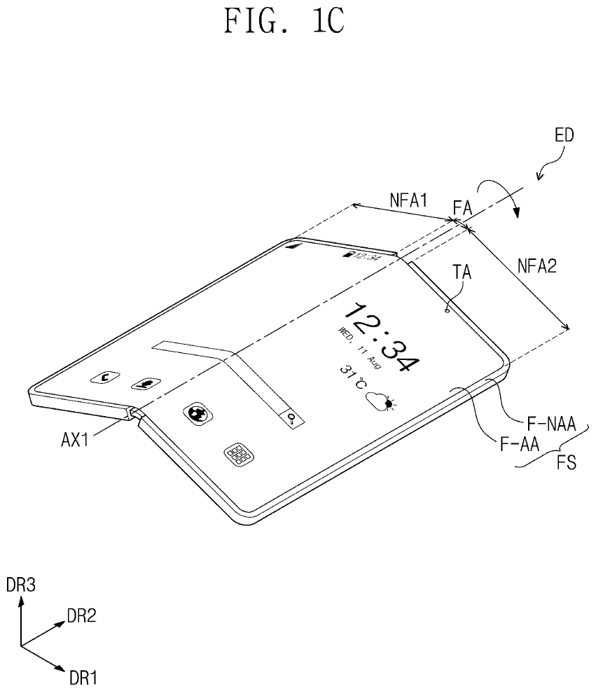

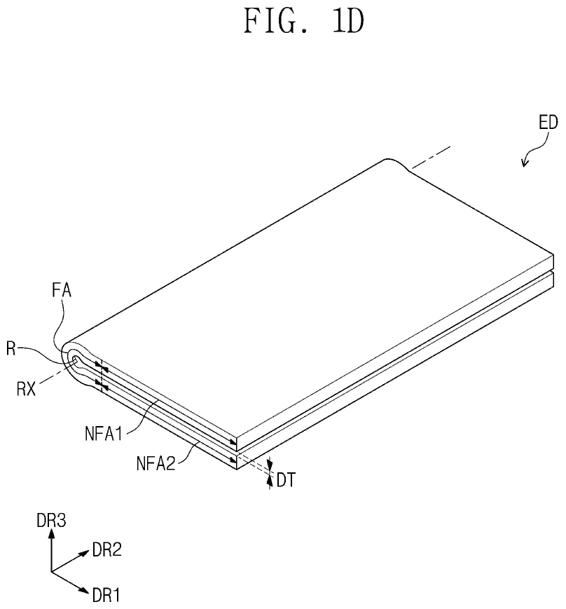

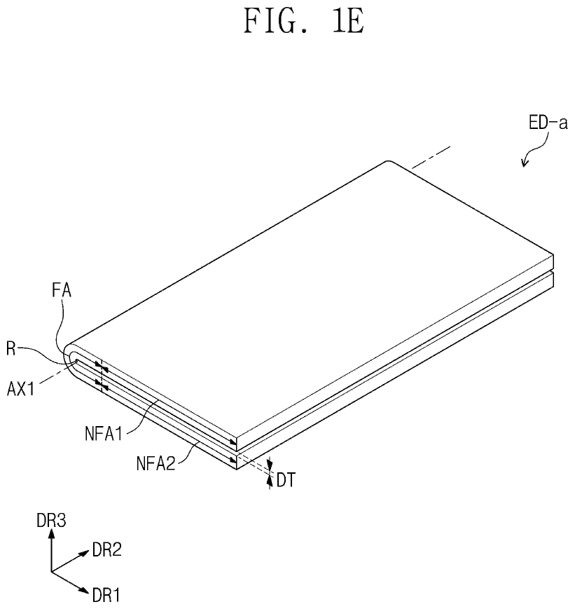

FIGS. 1A to 1E are each a perspective view of an electronic device according to one or more embodiments of the present disclosure. FIG. 1A is a perspective view illustrating an unfolded state of the electronic device according to one or more embodiments of the present disclosure. FIG. 1B is a perspective view illustrating a folding operation state of the electronic device according to one or more embodiments of the present disclosure. FIG. 1C is a perspective view illustrating a folding operation state of the electronic device according to one or more embodiments of the present disclosure. FIG. 1D is a perspective view illustrating a folded state of the electronic device according to one or more embodiments of the present disclosure. FIG. 1E is a perspective view illustrating a folded state of the electronic device according to one or more embodiments of the present disclosure.

Referring to FIGS. 1A to 1E, an electronic device ED according to one or more embodiments may be a device activated in response to an electrical signal. The electronic device ED may include one or more suitable embodiments. For example, the electronic device ED may include a mobile phone, a tablet computer, a car navigation unit, a laptop computer, a computer, a smart television, and/or the like. In the present disclosure, for example, in FIG. 1A, the electronic device ED is illustrated as a mobile phone.

The electronic device ED according to one or more embodiments may include a display surface FS defined by a first direction DR1 and a second direction DR2 crossing the first direction DR1. The electronic device ED may provide an image IM to a user through the display surface FS. The electronic device ED according to one or more embodiments may display the image IM in a third direction DR3 through the display surface FS parallel to each of the first direction DR1 and the second direction DR2. The display surface FS on which the image IM is displayed may correspond to the front surface of the electronic device ED. The image IM may include a static image as well as a dynamic image (including, e.g., a video). FIGS. 1A to 1C illustrate an internet search bar, a clock image, etc., as an example of the image IM.

In the present disclosure, the front surface (or upper surface) and the rear surface (or lower surface) of each component are defined based on a direction in which the image IM is displayed. The front surface and the rear surface are opposed to each other in the third direction DR3, and the normal directions of each of the front surface and the rear surface may be parallel to the third direction DR3.

The electronic device ED according to one or more embodiments may sense an external input applied from the outside. The external input may include one or more suitable forms of inputs provided from the outside of the electronic device ED. For example, the external input may include not only a touch by a part of a body such as a user's hand, but also an external input (for example, hovering) applied to the electronic device ED in proximity or applied to the electronic device ED while being adjacent within a set or predetermined distance. In one or more embodiments, the external input may have one or more suitable forms such as force, pressure, temperature, and/or light.

FIG. 1A illustrates an unfolded state of the electronic device ED. Referring to FIG. 1A, the display surface FS of the electronic device ED may include an active region F-AA and a peripheral region F-NAA. The active region F-AA may be a region activated in response to an electrical signal. The electronic device ED according to one or more embodiments may display the image IM through the active region F-AA. In one or more embodiments, one or more suitable types (kinds) of external inputs may be sensed in the active region F-AA. The peripheral region F-NAA is adjacent to the active region F-AA. The peripheral region F-NAA may have a lower light transmittance than the active region F-AA, and may have a set or predetermined color. The peripheral region F-NAA may surround the active region F-AA. Accordingly, the shape of the active region F-AA may be substantially defined by the peripheral region F-NAA. However, this is an example, and the peripheral region F-NAA may be disposed adjacent to only one side of the active region F-AA, or may not be provided. The electronic device ED according to one or more embodiments of the present disclosure may include one or more suitable shapes of active regions, but is not limited to any particular shape.

The display surface FS may further include a signal transmission region TA. In the present embodiment of FIG. 1A, it is illustrated that the signal transmission region TA is included inside the active region F-AA, but the present disclosure is not limited thereto. The signal transmission region TA may be included inside the peripheral region F-NAA, or may be surrounded by each of the active region F-AA and the peripheral region F-NAA.

The signal transmission region TA has a higher transmittance than the active region F-AA and the peripheral region F-NAA. Natural light, visible rays, or infrared rays may pass through the signal transmission region TA.

The electronic device ED may further include a sensor for capturing an external image by utilizing visible rays passing through the signal transmission region TA or determining, by utilizing infrared rays, whether an external object approaches. The sensor may overlap the signal transmission region TA. Accordingly, the electronic device ED including a sensor with improved reliability may be provided.

Referring to FIG. 1B, the electronic device ED according to one or more embodiments may be a foldable electronic device. The electronic device ED may include at least one folding region FA and non-folding regions NFA1 and NFA2 adjacent to the folding region FA. For example, the electronic device ED may be folded with respect to a first folding axis AX1. The first folding axis AX1 may be a virtual axis extending in the second direction DR2, and may extend along the second direction DR2 on the display surface FS.

In one or more embodiments, the non-folding regions NFA1 and NFA2 may be disposed adjacent to the folding region FA with the folding region FA therebetween. For example, a first non-folding region NFA1 may be disposed on one side of the folding region FA along the first direction DR1, and a second non-folding region NFA2 may be disposed on the other side of the folding region FA along the first direction DR1.

The electronic device ED may be in-folded with respect to the first folding axis AX1 so that one region of the display surface FS overlapping the first non-folding region NFA1 and the other region of the display surface FS overlapping the second non-folding region NFA2 face each other.

Referring to FIG. 1C, the electronic device ED according to one or more embodiments may be out-folded with respect to the folding axis AX1 so that one region of the display surface FS overlapping the first non-folding region NFA1 and the other region of the display surface FS overlapping the second non-folding region NFA2 are opposed to each other.

However, the present disclosure is not limited thereto, and the electronic device ED may be folded with respect to a plurality of folding axes so that the display surface FS (e.g., a portion of the display surface FS) and a portion of each of surfaces opposed to the display surface FS face each other, and the number of the folding axes and the number of non-folding regions according thereto are not specially limited. Referring to FIG. 1D, when the electronic device ED according to one or more embodiments is in-folded, at least a part of the folding region FA may have a set or predetermined curvature. In an in-folded state, the folding region FA may have a center of curvature RX inside the folding region FA, and electronic device ED may be folded with a set or predetermined radius of curvature R with respect to the center of curvature RX. According to one or more embodiments, the radius of curvature R may be greater than a spacing DT between the first non-folding region NFA1 and the second non-folding region NFA2. Accordingly, in one or more embodiments, when viewed in the second direction DR2, the folding region FA may be folded like a dumbbell shape (e.g., one half of a dumbbell shape).

Referring to FIG. 1E, an electronic device ED-a according to one or more embodiments may be in-folded with a set or predetermined radius of curvature R. At this time, the spacing DT between a part extending to the first non-folding region NFA1 from the folding region FA and a part extending to the second non-folding region NFA2 from the folding region FA may be constant along the first direction DR1. In this case, when viewed in the second direction DR2, the folding region FA may be folded like a “U” shape, but the present disclosure is not limited thereto.

The electronic device ED according to one or more embodiments may operate in only one mode selected from modes of being in-folded or out-folded around one folding axis, or may operate such that in-folding and out-folding are mutually repeated (e.g., are alternated), but the present disclosure is not limited thereto. The electronic device ED according to one or more embodiments may be configured to select any one among an unfolding operation, an in-folding operation, and an out-folding operation. It is illustrated that the electronic device ED according to one or more embodiments is folded with respect to one folding axis, but the number of folding axes defined in the electronic device ED is not limited thereto, and the electronic device ED may be folded with respect to a plurality of folding axes.

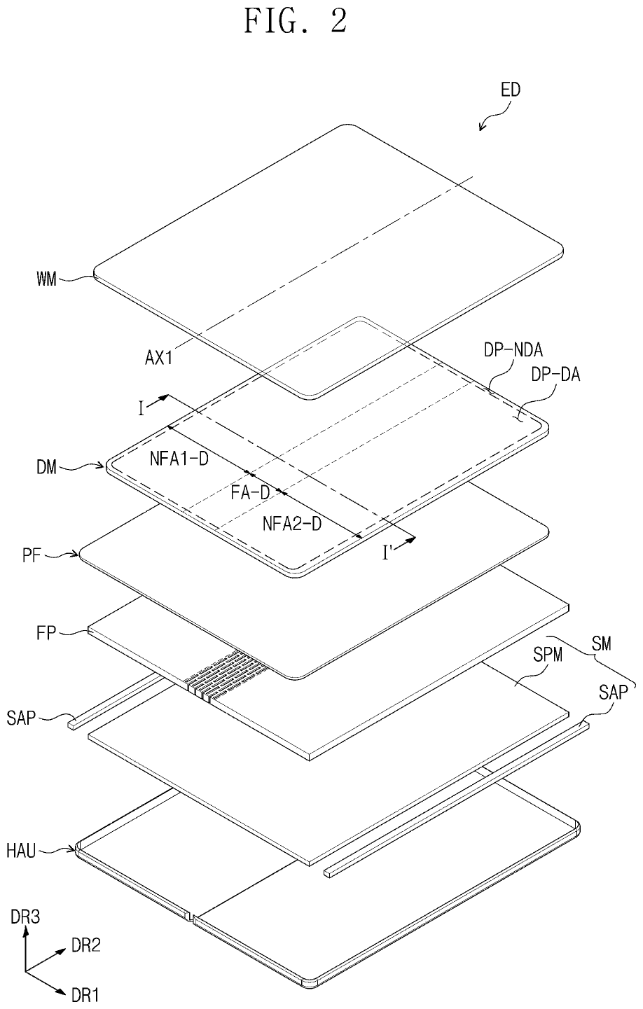

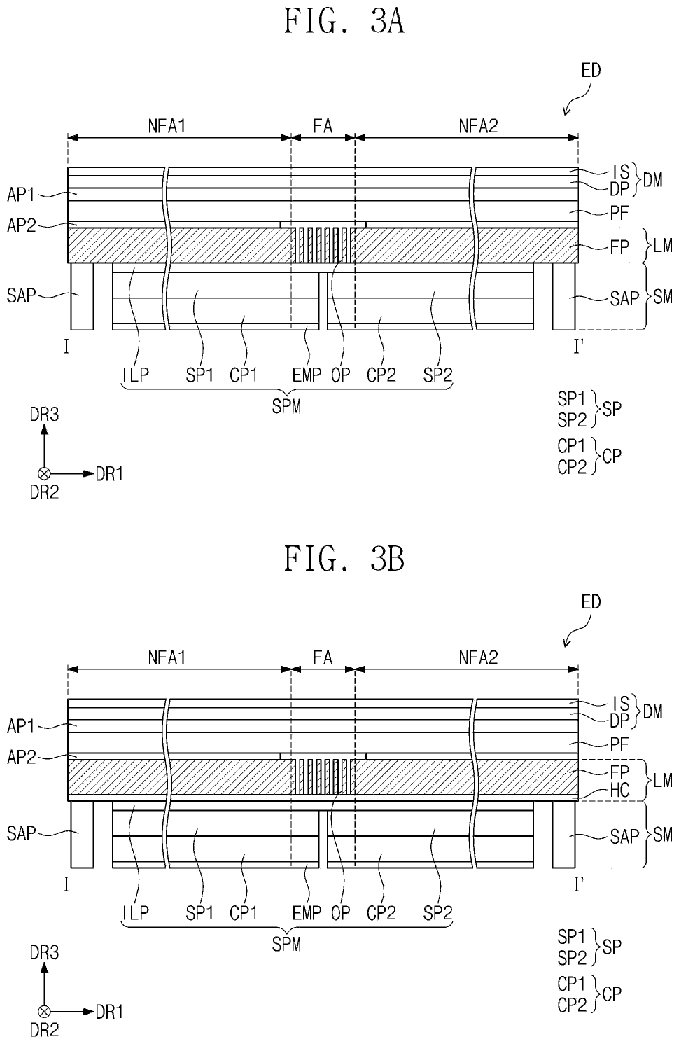

FIG. 2 is an exploded perspective view of an electronic device according to one or more embodiments. FIG. 2 illustrates an exploded perspective view of the electronic device according to one or more embodiments illustrated in FIG. 1A. FIG. 2 illustrates, for example, only some of components included in an electronic device ED. FIGS. 3A and 3B are each a cross-sectional view of the electronic device according to one or more embodiments of the present disclosure. FIGS. 3A and 3B are each a cross-sectional view illustrating a cross-section taken along line I-I′ of FIG. 2.

Referring to FIGS. 2 and 3A, the electronic device ED according to one or more embodiments may include a display module DM and a support plate FP disposed under the display module DM. The electronic device ED according to one or more embodiments may include the display module DM, the support plate FP, a support member SM, and a protective layer PF.

The electronic device ED may include a window member WM disposed on the display module DM, and the window member WM may cover the entire outside of the display module DM. The window member WM may have a shape corresponding to the shape of the display module DM. In some embodiments, the electronic device ED may include a housing HAU that accommodates the display module DM and the support plate FP. The housing HAU may be coupled to the window member WM. In one or more embodiments, the housing HAU may further include a hinge structure for being easily folded or bent.

The window member WM may include a window and an adhesive layer. In the electronic device ED according to one or more embodiments, the window may include an optically transparent insulating material. The window may be a glass substrate or a polymer substrate. For example, the window may be a reinforced glass substrate which has been subjected to reinforcement treatment. The adhesive layer may be disposed between the display module DM and the window. The adhesive layer may be an optically clear adhesive film (OCA) or an optically clear adhesive resin layer (OCR). In one or more embodiments, the adhesive layer may not be provided.

The display module DM may display an image in response to an electrical signal, and may be to transmit/receive information about an external input. The display module DM may define a display region DP-DA and a non-display region DP-NDA. The display region DP-DA may be defined as a region from which an image provided from the display module DM is emitted.

The non-display region DP-NDA is adjacent to the display region DP-DA. For example, the non-display region DP-NDA may surround the display region DP-DA. However, this is illustrated as an example, and the non-display region DP-NDA may be defined to have one or more suitable shapes, and the present disclosure is not limited thereto. According to one or more embodiments, the display region DP-DA of the display module DM may correspond to at least a part of the active region F-AA (see, e.g., FIG. 1A), and the non-display region DP-NDA may correspond to the peripheral region F-NAA (see, e.g., FIG. 1A).

The display module DM may include a display panel DP and an input sensor IS disposed on the display panel DP. In one or more embodiments, the display module DM may further include an optical layer disposed on the input sensor IS. The optical layer may function to decrease reflection by external light. For example, the optical layer may include a polarization layer or a color filter layer.

The display panel DP may be a light-emitting display panel, but the present disclosure is not limited thereto. For example, the display panel DP may be an organic light-emitting display panel or an inorganic light-emitting display panel. A light-emitting element of the organic light-emitting display panel may include an organic light-emitting material. A light-emitting element of the inorganic light-emitting display panel may include quantum dots or quantum rods. The display panel DP according to one or more embodiments may include a micro LED element (e.g., an LED element in a micro scale) and/or a nano LED element (e.g., an LED element in a nano scale), but the present disclosure is not limited thereto.

The display panel DP may include a base layer, a circuit element layer disposed on the base layer, a display element layer disposed on the circuit element layer, and a thin-film encapsulation layer disposed on the display element layer. The base layer may include a polymer material. For example, the base layer may include polyimide.

The circuit element layer may include an organic layer, an inorganic layer, a semiconductor pattern, a conductive pattern, a signal line, etc. An organic layer, an inorganic layer, a semiconductor layer, and a conductive layer may be formed on the base layer through coating and deposition. Then, the organic layer, the inorganic layer, the semiconductor layer and the conductive layer are selectively patterned by performing a photolithography process multiple times, so that a semiconductor pattern, a conductive pattern and a signal line may be formed.

The display element layer may include a light-emitting element. The light-emitting element is electrically connected to at least one transistor. The thin-film encapsulation layer may be disposed on the circuit element layer so as to encapsulate the display element layer. The thin-film encapsulation layer may include an inorganic layer, an organic layer, and an inorganic layer which are sequentially stacked, but the stack structure of the thin-film encapsulation layer is not specially limited thereto.

The input sensor IS may include a plurality of sensing electrodes for sensing an external input. The input sensor IS may be a capacitive sensor, but is not specially limited thereto. As an example, the input sensor IS may be capacitively driven, and may sense, over the entire active region F-AA (see, e.g., FIG. 1A), the position and/or strength of a user's hand applied thereto. The input sensor IS may include sensing electrodes insulated from each other, routing lines respectively connected to corresponding sensing electrodes, and at least one sensing insulating layer.

In one or more embodiments, during manufacturing of the display panel DP, the input sensor IS may be formed directly on the thin-film encapsulation layer through a substantially continuous process. In this case, it may be expressed that the input sensor IS is “directly disposed” on the display panel DP. The wording “directly disposed” may mean that a third component is not disposed between the input sensor IS and the display panel DP. For example, a separate adhesive member may not be disposed between the input sensor IS and the display panel DP, but the present disclosure is not limited thereto. The input sensor IS may be manufactured as a panel separate from the display panel DP, and may thus be attached to the display panel DP by an adhesive layer.

The display module DM may be a flexible display module. The display module DM may include a folding display part FA-D and non-folding display parts NFA1-D and NFA2-D. The folding display part FA-D may be a part corresponding to a folding region FA (see, e.g., FIG. 1A), and the non-folding display parts NFA1-D and NFA2-D may be parts corresponding to the non-folding regions NFA1 and NFA2 (see, e.g., FIG. 1A).

The folding display part FA-D may correspond to a part folded or bent with respect to a first folding axis AX1. The display module DM may include a first non-folding display part NFA1-D and a second non-folding display part NFA2-D, and the first non-folding display part NFA1-D and the second non-folding display part NFA2-D may be spaced apart from (separated from) each other with the folding display part FA-D therebetween.

The support part LM may be disposed under the display module DM. The support part LM may include a support plate FP. The support plate FP may be disposed under the display panel DP to support the display panel DP. The support plate FP may be provided as an integrated plate overlapping the folding region FA, the first non-folding region NFA1, and the second non-folding region NFA2.

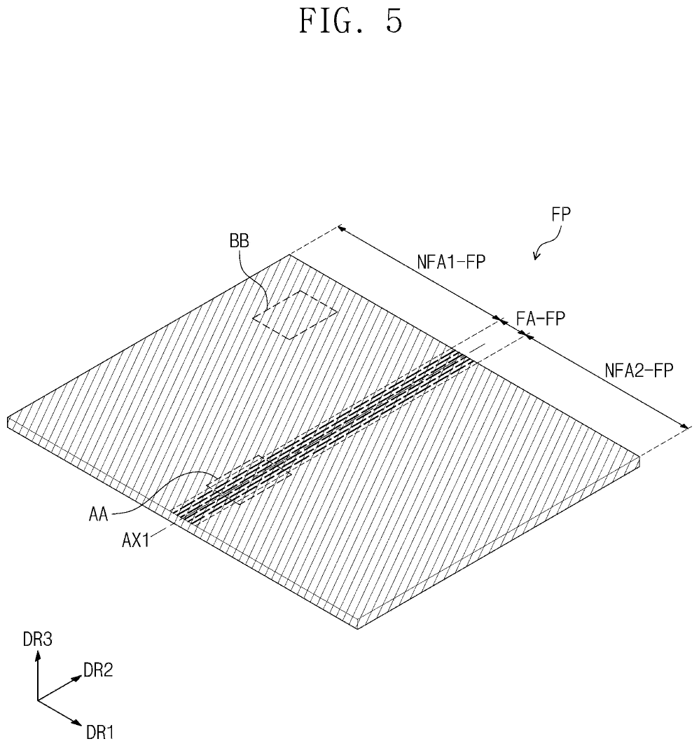

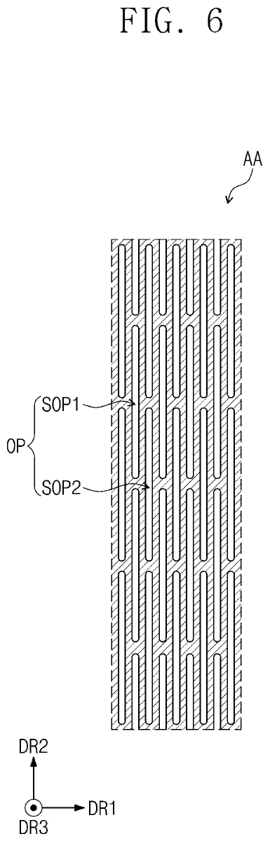

In one or more embodiments, a plurality of openings OP overlapping the folding region FA may be defined in the support plate FP. The plurality of openings OP may be formed so as to penetrate, in the third direction DR3, a part of the support plate FP overlapping the folding region FA. The flexibility of a part of the support plate FP corresponding to the folding region FA may be improved by the plurality of openings OP. A more detailed description of this will be made with reference to FIGS. 5 and 6.

The support plate FP may include a reinforced fiber composite. The reinforced fiber composite may include a glass fiber reinforced plastic (GFRP), but the present disclosure is not limited thereto. The support plate FP may include a carbon fiber reinforced plastic (CFRP), an aramid fiber reinforced plastic, and/or the like.

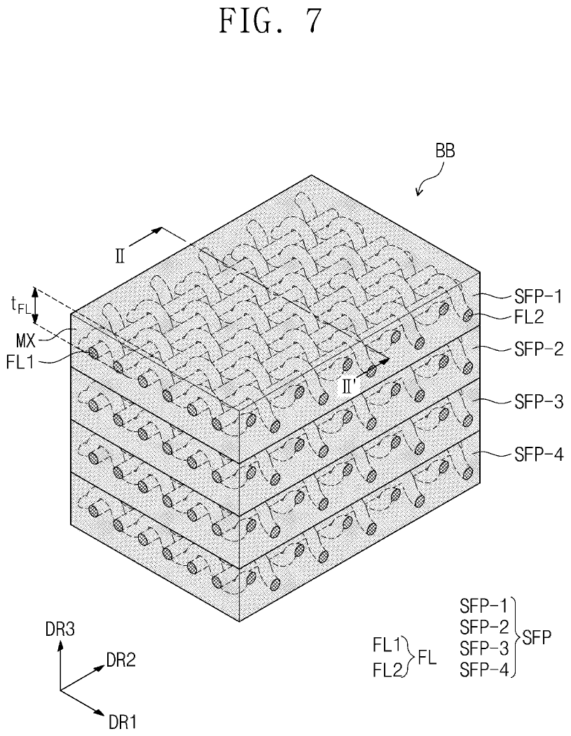

The support plate FP may include the reinforced fiber composite such as the glass fiber reinforced plastic and thus become thinner and more lightweight. The support plate FP including the reinforced fiber composite may be formed by stacking sub-support plates SFP formed utilizing a matrix part MX (see, e.g., FIG. 7) and reinforced fibers FL1 and FL2.

The thickness of the support plate FP may be changed in consideration of mechanism design characteristics of the electronic device ED, mechanical properties of the electronic device ED, etc. For example, the thickness of the support plate FP may be about 100 μm to about 300 μm, but the present disclosure is not limited thereto.

The protective layer PF may be disposed between the display module DM and the support plate FP. The protective layer PF may be disposed under the display module DM and protect the rear surface of the display module DM. The protective layer PF may overlap the entire display module DM. The protective layer PF may include a polymer material. For example, the protective layer PF may be a polyimide film or a polyethyleneterephthalate film. However, this is an example, and the material of the protective layer PF is not limited thereto.

The electronic device ED according to one or more embodiments may further include the support member SM. The support member SM may include a support part SPM and a filling part SAP. The support part SPM may overlap the most region of the display module DM. The filling part SAP may be disposed outside the support part SPM and overlap the outer region of the display module DM.

The support member SM may include at least one of a support layer SP or a cushion layer CP. In one or more embodiments, the support member SM may further include at least one of a shielding layer EMP or an interlayer-bonding layer ILP.

For example, the support layer SP may include a metal material or a reinforced fiber composite. The support layer SP may be disposed under the support plate FP. The support layer SP may be a thin-film metal substrate. In one or more embodiments, the support layer SP may be formed of a reinforced fiber composite including a glass fiber and/or a carbon fiber. When the support layer SP may be a thin-film metal substrate, the support layer SP may include stainless steel, aluminum, or a combination thereof. The support layer SP may have a function of heat dissipation, electromagnetic wave shielding, and/or the like.

In one or more embodiments illustrated in FIG. 3A, the cushion layer CP may be disposed under the support layer SP. The cushion layer CP may prevent or reduce the support plate FP from being pressed or plastically deformed due to an external impact and force. The cushion layer CP may improve the impact resistance of the electronic device ED. The cushion layer CP may include an elastomer such as sponge, foam, or a urethane resin. In one or more embodiments, the cushion layer CP may be formed including at least one of an acryl-based polymer, a urethane-based polymer, a silicone-based polymer, and/or an imide-based polymer, but the present disclosure is not limited thereto.

In one or more embodiments, it is illustrated in FIG. 3A, etc., that the cushion layer CP is disposed under the support layer SP, but the present disclosure is not limited thereto, and the cushion layer CP may be disposed on top of the support layer SP.

In the electronic device ED according to one or more embodiments, the configuration of the support member SM may be changed depending on the size, shape, operation characteristics of the electronic device ED. For example, in one or more embodiments, the support member SM may include a plurality of support layers SP or a plurality of cushion layers CP. In one or more embodiments, any one of the support layer SP and/or the cushion layer CP may not be provided in the support member SM, or the support member SM may include only the support layer SP or only the cushion layer CP.

The support layer SP may include a first sub-support layer SP1 and a second sub-support layer SP2 which are spaced apart from (separated from) each other in the first direction DR1. The first sub-support layer SP1 and the second sub-support layer SP2 may be spaced apart from (separated from) each other in a part corresponding the first folding axis AX1. The support layer SP may be provided as the first sub-support layer SP1 and the second sub-support layer SP2 spaced apart from (separated from) each other in the folding region FA, and may thus improve the folding and bending characteristics of the electronic device ED.

In one or more embodiments, the cushion layer CP may include a first sub-cushion layer CP1 and a second sub-cushion layer CP2 spaced apart from (separated from) each other in the first direction DR1. The first sub-cushion layer CP1 and the second sub-cushion layer CP2 may be spaced apart from (separated from) each other in a part corresponding the first folding axis AX1. The cushion layer CP may be provided as the first sub-cushion layer CP1 and the second sub-cushion layer CP2 spaced apart from (separated from) each other in the folding region FA, and may thus improve the folding and bending characteristics of the electronic device ED.

The support member SM may further a shielding layer EMP. The shielding layer EMP may be an electromagnetic wave shielding layer or a heat dissipation layer. In one or more embodiments, the shielding layer EMP may function as a bonding layer. The support member SM and the housing HAU may be bonded utilizing the shielding layer EMP. It is illustrated in FIG. 3A, etc., that the shielding layer EMP is disposed under the cushion layer CP, but the present disclosure is not limited thereto.

The support member SM may further include the interlayer-bonding layer ILP disposed on the support layer SP. The interlayer-bonding layer ILP may bond the support plate FP and the support member SM. The interlayer-bonding layer ILP may be provided in a form of a bonding resin layer or an adhesive tape. For example, the interlayer-bonding layer ILP may overlap the entire folding display part FA-D, but the present disclosure is not limited thereto, and a part overlapping the folding display part FA-D may be removed or not included (e.g., may be excluded).

The filling part SAP may be disposed in the outer region of the support layer SP and the cushion layer CP. The filling part SAP may be disposed between the support plate FP and the housing HAU. The filling part SAP may fill a space between the support plate FP and the housing HAU, and may fix the support plate FP.

In one or more embodiments, the electronic device ED according to one or more embodiments may further include at least one of adhesive layers AP1 and/or AP2. For example, a first adhesive layer AP1 may be disposed between the display module DM and the protective layer PF, and a second adhesive layer AP2 may be disposed between the protective layer PF and the support part LM. At least one of the adhesive layers AP1 and/or AP2 may be an optically clear adhesive film (OCA) or an optically clear adhesive resin layer (OCR). However, the present disclosure is not limited thereto, and at least one of the adhesive layers AP1 and/or AP2 may have a low transmittance of equal to or less than about 80%.

In one or more embodiments, the electronic device ED according to one or more embodiments may further have an adhesive layer disposed between the support layer SP and the cushion layer CP.

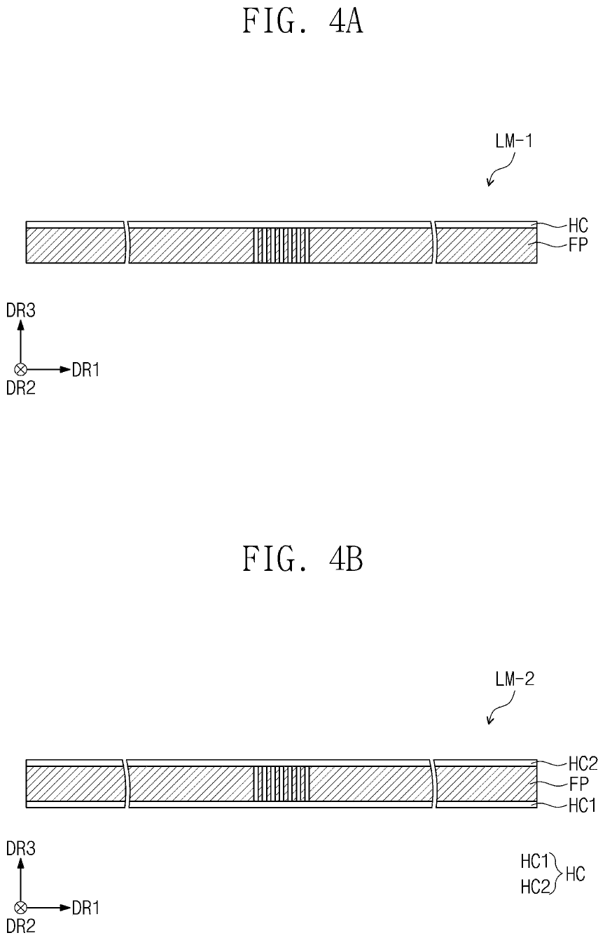

Compared to FIG. 3A, FIG. 3B illustrates a cross-sectional view of an electronic device ED according to one or more embodiments in which a support part LM further includes a hard coat layer HC. FIG. 4A is a cross-sectional view schematically illustrating a support part LM-1 according to one or more embodiments of the present disclosure. FIG. 4B is a cross-sectional view schematically illustrating another support part LM-2 according to one or more embodiments of the present disclosure.

In description of the electronic device ED according to one or more embodiments, content duplicated with those described above with reference to FIGS. 1A to 3A may not be described again, and differences may be mainly described.

Referring to FIGS. 3B, 4A, and 4B, in one or more embodiments, the support part LM may include a support plate FP and a hard coat layer HC. The hard coat layer HC may be disposed on top of and/or under the support plate FP. The hard coat layer HC may be disposed directly on the upper surface and/or the lower surface of the support plate FP without a separate adhesive member. The hard coat layer HC may be formed on the upper surface and/or the lower surface of the support plate FP utilizing a UV curing resin or a thermosetting resin capable of improving a modulus of the support plate FP. For example, the hard coat layer HC may be formed through a coating method, such as molding, screen printing, applicator, or bar coater, of an epoxy resin, a urethane resin, a polyester resin, a silicone resin, and/or the like, but the present disclosure is not limited thereto.

In one or more embodiments, because the hard coat layer HC is formed on the upper surface and/or the lower surface of the support plate FP, the support plate FP may have an improved modulus. The hard coat layer HC may improve the flexural modulus of the support plate FP by about 10% to about 20%. For example, the flexural modulus may be measured by a 3-point bending method. The thickness of the hard coat layer HC may be changed in consideration of the mechanical properties of the electronic device ED. For example, the thickness of the hard coat layer HC may be about 1 μm to about 20 μm, but the present disclosure is not limited thereto.

Referring to FIG. 3B, the hard coat layer HC according to one or more embodiments may be disposed under the support plate FP. The hard coat layer HC may be disposed directly on the lower surface of the support plate FP, and may not be disposed on the upper surface of the support plate FP. The support plate FP may have an improved modulus and improved visibility of a lower step because of the hard coat layer HC disposed thereunder.

FIGS. 4A and 4B are cross-sectional views respectively illustrating different embodiments of the support part LM illustrated in FIG. 3B. FIG. 4A is a cross-sectional view illustrating a support part LM-1 in which the hard coat layer HC is disposed on top of the support plate FP, compared to the support part LM illustrated in FIG. 3B. FIG. 4B is a cross-sectional view illustrating a support part LM-2 in which the hard coat layer HC is disposed on top of and under the support plate FP, compared to the support part LM illustrated in FIG. 3B.

Referring to FIG. 4A, the support part LM-1 according to one or more embodiments may include the support plate FP and the hard coat layer HC disposed on top of the support plate FP. The hard coat layer HC disposed on top of the support plate FP may be disposed adjacent to the display panel DP (see, e.g., FIG. 3B). The hard coat layer HC may be disposed directly on the upper surface of the support plate FP, and may not be disposed on the lower surface of the support plate FP. The hard coat layer HC formed on top of the support plate FP may contribute to improving an impact resistance function of the display panel DP and surface quality of the support plate FP.

Referring to FIG. 4B, the support part LM-2 according to one or more embodiments includes the support plate FP and hard coat layers HC disposed on top of and under the support plate FP. The hard coat layer HC may include a first hard coat layer HC1 disposed under the support plate FP and a second hard coat layer HC2 disposed on top of the support plate FP. The hard coat layer HC may be disposed directly on both (e.g., simultaneously) the upper surface and the lower surface of the support plate FP. The first hard coat layer HC1 formed under the support plate FP may contribute to improving the visibility of a lower step. In one or more embodiments, the second hard coat layer HC2 formed on top of the support plate FP may contribute to improving an impact resistance function of the display panel DP and surface quality of the support plate FP. For example, because the support plate FP includes the hard coat layers HC formed on top thereof and thereunder, the electronic device ED according to one or more embodiments may have more improved mechanical properties and display quality.

FIG. 5 is a perspective view of a support plate according to one or more embodiments of the present disclosure. FIG. 6 is a plan view illustrating a part of the support plate according to one or more embodiments of the present disclosure. FIG. 6 is an enlarged plan view of the support plate illustrating region AA in FIG. 5.

Referring to FIGS. 5 and 6, the support plate FP may include a plate folding part FA-FP and plate non-folding parts NFA1-FP and NFA2-FP. A first plate non-folding part NFA1-FP and a second plate non-folding part NFA2-FP may be spaced apart from (separated from) each other in the first direction DR1 with the plate folding part FA-FP therebetween.

The plate folding part FA-FP may correspond to the folding region FA (see, e.g., FIG. 1A), and the plate non-folding parts NFA1-FP and NFA2-FP may correspond to the non-folding regions NFA1 and NFA2 (see, e.g., FIG. 1A). The plate folding part FA-FP may overlap the folding display part FA-D (see, e.g., FIG. 2), and the plate non-folding parts NFA1-FP and NFA2-FP may overlap the non-folding display parts NFA1-D and NFA2-D (see, e.g., FIG. 2).

A lattice pattern may be defined in the plate folding part FA-FP. For example, a plurality of openings OP may be defined in the plate folding part FA-FP. The plurality of openings OP may be arranged in a form of a lattice having a set or predetermined rule, and may form a lattice pattern in the plate folding part FA-FP. For example, when viewed on a plane defined by the first direction DR1 and the second direction DR2, the width of each of the openings OP in the first direction DR1 may be smaller than the width of each of the openings OP in the second direction DR2. The widths of the openings OP in the first direction DR1 perpendicular to the extending direction of the first folding axis AX1 may be smaller than the widths of the openings OP in the second direction DR2 parallel to the extending direction of the first folding axis AX1.

The plurality of openings OP may be provided in a plurality of rows. The plurality of openings OP may be provided in the plurality of rows arranged in a staggered manner. In one or more embodiments, the plurality of openings OP may include a plurality of first opening SOP1 and a plurality of second opening SOP2 arranged in a staggered manner in the first direction DR1. The plurality of first openings SOP1 arranged in one row (e.g., one first direction DR1 row) may be spaced apart from (separated from) each other in the first direction DR1, and each of plurality of first openings SOP1 may extend in the second direction DR2. The plurality of second openings SOP2 may be spaced apart from (separated from) the plurality of first openings SOP1 in the first direction DR1. The plurality of second openings SOP2 arranged in one row (e.g., one first direction DR1 row) may be spaced apart from (separated from) each other in the first direction DR1, and each of plurality of second openings SOP2 may extend in the second direction DR2. In addition, the plurality of first openings SOP1 arranged in one column (e.g., one second direction DR2 column) may be spaced apart from (separated from) each other in the second direction DR2, and the plurality of second openings SOP2 arranged in one column (e.g., one second direction DR2 column) may be spaced apart from (separated from) each other in the second direction DR2.

The plurality of openings OP may be formed in one or more suitable ways. For example, the plurality of openings OP may be formed through a laser process or a micro blast process, but the present disclosure is not limited thereto.

The area of the plate folding part FA-FP may be reduced by the plurality of openings OP. Accordingly, the plate folding part FA-FP in which the plurality of openings OP are defined may have improved flexibility than the plate folding part FA-FP in which the plurality of openings OP are not defined.

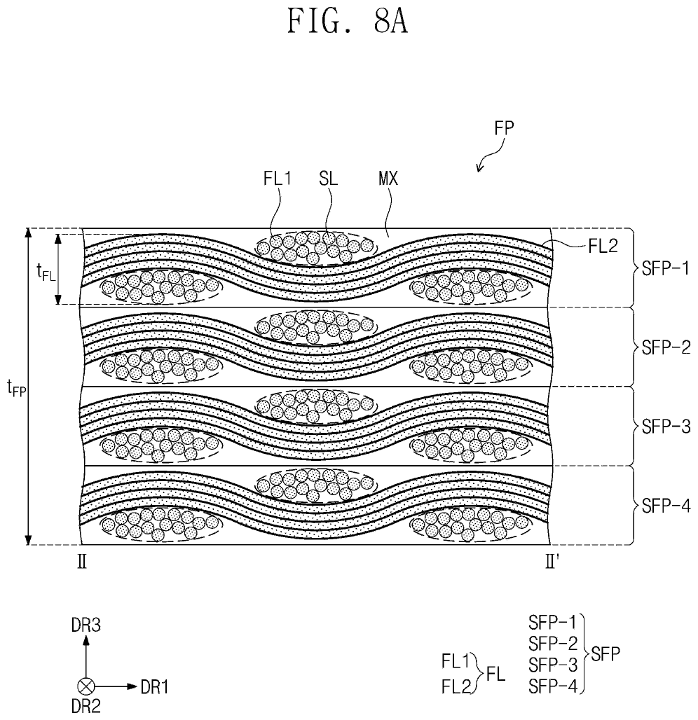

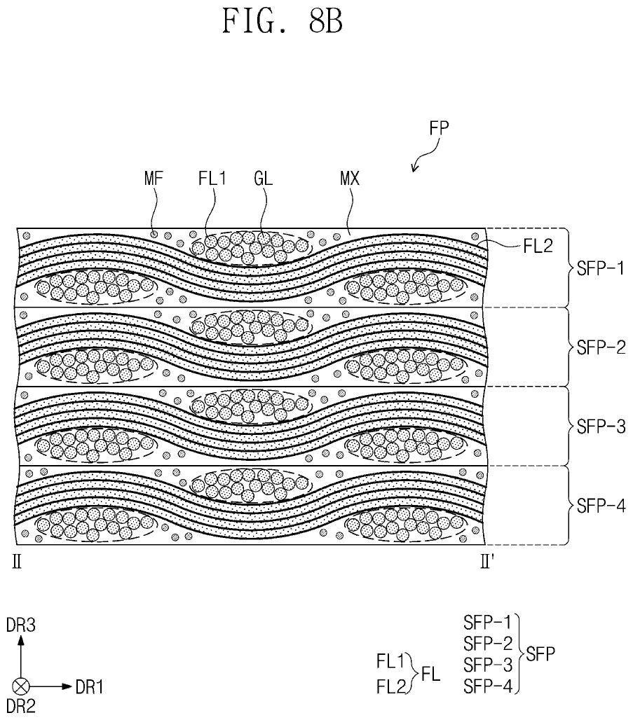

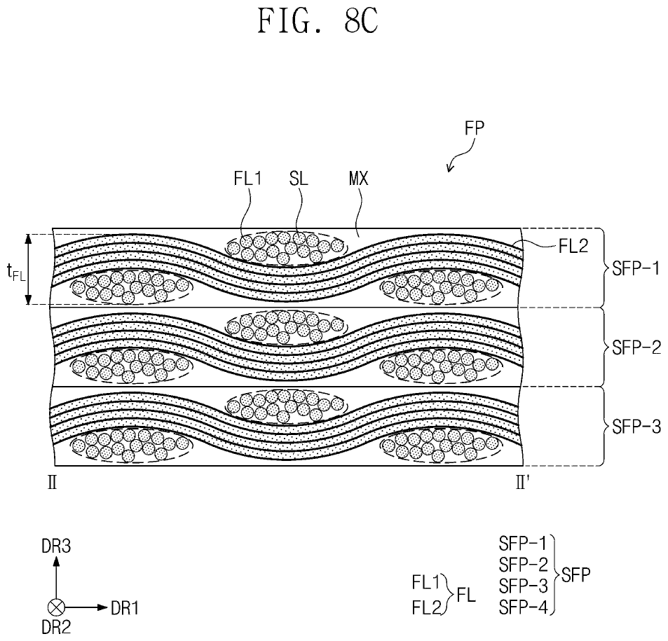

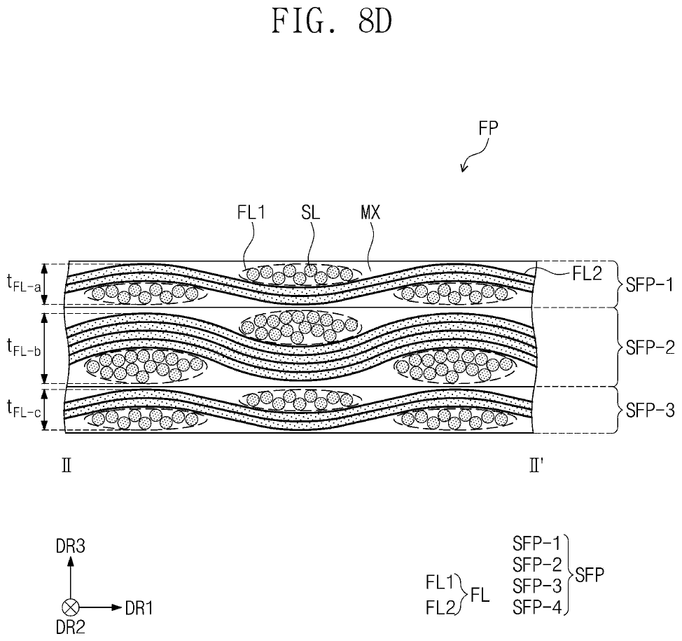

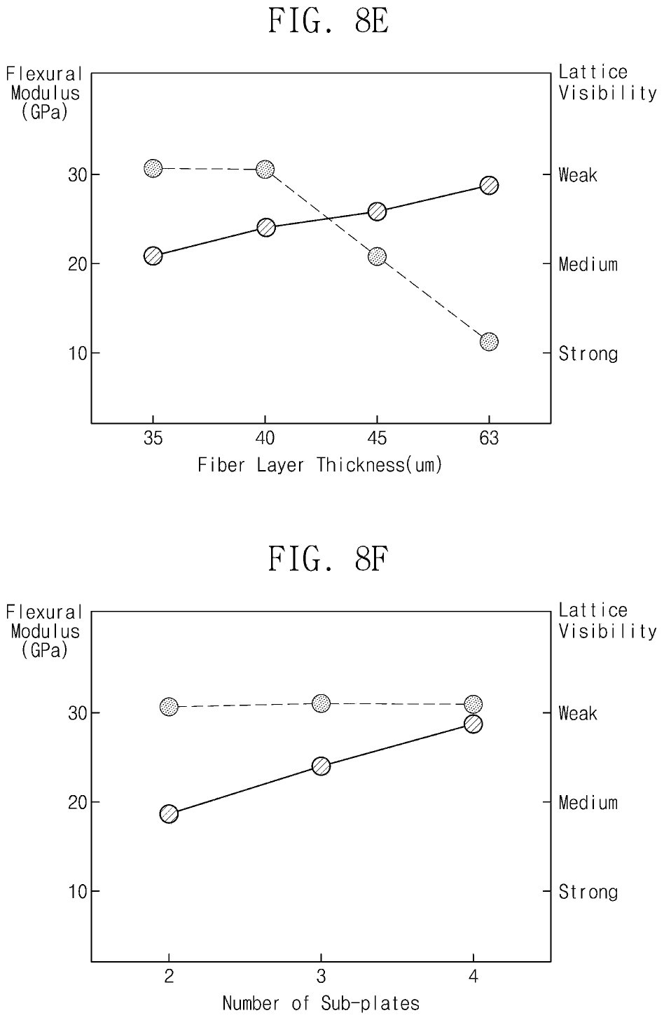

FIG. 7 is a perspective view illustrating a part of a support plate according to one or more embodiments of the present disclosure. FIG. 7 is an enlarged perspective view of the support plate illustrating region BB in FIG. 5. FIGS. 8A to 8D are each an enlarged cross-sectional view of the support plate according to one or more embodiments of the present disclosure. FIGS. 8A to 8D are enlarged cross-sectional views taken along line II-II′ of the support plate of FIG. 7, according to one or more embodiments of the present disclosure.

Referring to FIGS. 7 and 8A to 8D, a support plate FP may include a plurality of sub-plates SFP. The plurality of sub-plates SFP may be sequentially stacked along the third direction DR3. The plurality of sub-plates SFP may be sequentially stacked along the thickness direction of the electronic device ED (see, e.g., FIG. 3A). The plurality of sub-plates SFP may include two to five sub-plates SFP, or three to five sub-plates SFP.

FIGS. 7, 8A and 8B exemplarily illustrate four sub-plates SFP1, SFP2, SFP3, and SFP4 sequentially stacked along the third direction DR3. The support plate FP according to one or more embodiments may include a first sub-plate SFP-1 disposed adjacent to the display panel DP (see, e.g., FIG. 3A), a second sub-plate SFP-2 disposed under the first sub-plate SFP-1, a third sub-plate SFP-3 disposed under the second sub-plate SFP-2, and a fourth sub-plate SFP-4 disposed under the third sub-plate SFP-3. However, in one or more embodiments, the number of the sub-plates SFP is not limited thereto, and may be differently designed according to the thickness, strength, and/or the like of the support plate FP disposed in the electronic device ED (see, e.g., FIG. 3A). For example, as illustrated in FIGS. 8C and 8D, the support plate FP may include three sub-plates SFP stacked in the third direction DR3. In addition, the present disclosure is not limited thereto, and the support plate FP may include, for example, five sub-plates SFP stacked in the third direction DR3.

The sub-plates SFP may each include a matrix part (e.g., a matrix) MX and reinforced fibers FL1 and FL2. The reinforced fibers FL1 and FL2 may be glass fibers. The reinforced fibers FL1 and FL2 may each extend in one direction, and may be arranged in a direction crossing the extending direction. For example, a first reinforced fiber FL1 may extend in the second direction DR2, and may be arranged in the first direction DR1. A second reinforced fiber FL2 may extend in the first direction DR1, and may be arranged in the second direction DR2.

The reinforced fibers FL1 and FL2 included in the support plate FP according to one or more embodiments may be each composed of a single strand. The reinforced fibers FL1 and FL2 may be each composed of a set of a plurality of sub-reinforced fibers SL. For example, the plurality of sub-reinforced fibers SL may be bound as one bundle to constitute one first reinforced fiber FL1 strand. In one or more embodiments, the plurality of sub-reinforced fibers SL may be bound as one bundle to constitute one second reinforced fiber FL2 strand.

In one or more embodiments, the first reinforced fibers FL1 and the second reinforced fibers FL2 may be woven with each other to form the fiber layer FL. The fiber layer FL may include the woven reinforced fibers FL1 and FL2. For example, with respect to one first reinforced fibers FL1, the first reinforced fibers FL1 may be disposed alternately above and below the second reinforced fibers FL2 arranged parallel along the second direction DR2. In some embodiments, with respect to one second reinforced fibers FL2, the second reinforced fibers FL2 may be disposed alternately above and below the first reinforced fibers FL1 arranged parallel along the first direction DR1. The reinforced fibers FL1 and FL2 are alternately arranged along the first direction DR1 and the second direction DR2 respectively so that the fiber layer FL may have a woven shape on a plane.

The fiber layer FL may be disposed inside the matrix part MX. The first and second reinforced fibers FL1 and FL2 forming the fiber layer FL may be disposed dispersed in the matrix part MX. The matrix part MX may include a polymer resin. For example, the matrix part MX may include at least one of an epoxy-based resin, a polyester-based resin, a polyimide-based resin, a polycarbonate-based resin, a polypropylene-based resin, a polybutylene-based resin, and/or a vinyl ester-based resin. In the support plate FP according to one or more embodiments, the matrix part MX may include a novolac epoxy resin which is stiff for improving mechanical properties and has characteristics of the glass transition temperature (Tg) of about 175° C. to about 280° C., but the material of the matrix part MX is not limited to the above examples. The matrix part MX may fill the space between the first and second reinforced fibers FL1 and FL2, and may bring the first and second reinforced fibers FL1 and FL2 closer to each other.

The sub-plates SFP may include inorganic particles MF dispersed in the matrix part MX. For example, the inorganic particles MF may include silica, barium sulphate, barium titanate, titanium oxide, sintered talc, titanium oxide, zinc borate, zinc titanate, clay, alumina, mica, tin oxide such as SnO₂, zinc tin oxide, boehmite, and/or the like. The inorganic particles MF dispersed in the matrix part MX may complement the strength of the support plate FP.

The sub-plates SFP may each include the reinforced fibers FL1 and FL2 in an amount of about 48 wt % to about 52 wt % with respect to the total weight of the sub-plates SFP. For example, the first sub-plate SFP-1 may include the reinforced fibers FL1 and FL2 in an amount of about 48 wt % to about 52 wt % with respect to the total weight of the first sub plate SFP-1. The first to fourth sub plates SFP-1, SFP-2, SFP-3, and SFP-4 according to one or more embodiments may each include the reinforced fibers FL1 and FL2 in substantially the same content (e.g., amount) range, or in mutually different content (e.g., amount) ranges. The sub-plates SFP including the reinforced fibers FL1 and FL2 in the above content (e.g., amount) range may contribute to improving the modulus of the support plate FB.

The sub-plates SFP may each include the matrix part MX in an amount of about 48 wt % to about 52 wt % with respect to the total weight of the sub-plates SFP. For example, the first sub-plate SFP-1 may include the matrix part MX in an amount of about 48 wt % to about 52 wt % with respect to the total weight of the first sub-plate SFP-1. When the inorganic particles MF are dispersed in the matrix part MX, about 20 wt % to about 22 wt % of the inorganic particles MF may be included with respect to the total weight of the matrix part MX.

The sub-plates SFP according to one or more embodiments may each include the fiber layer FL having a set or predetermined thickness t_{FL}. The thickness t_{FL} of the fiber layer FL included in each of the sub-plates SFP may be changed according to the thickness t_{FP} of the support plate FP. For example, the sub-plates SFP may each include the fiber layer FL designed to have a thickness in a specific range according to the thickness t_{FP} of the support plate FP. Accordingly, the support plate FP according to one or more embodiments may have an improved modulus, and the grain-direction waviness thereof may not be viewed on the surface, thereby improving the surface quality of the support plate FP.

The thickness t_{FP} of the support plate FP according to one or more embodiments may be about 100 μm to about 300 μm. The sub-plates SFP may include the fiber layer FL designed to have a set or predetermined thickness t_{FL} according to the thickness t_{FP} of the support plate FP described above. For example, when the thickness t_{FP} of the support plate FP is about 100 μm to about 200 μm, the thickness t_{FL} of the fiber layer FL may be equal to or more than about 30 μm and less than about 50 μm. When the thickness t_{FP} of the support plate FP is more than about 200 μm and equal to or less than about 300 μm, the thickness t_{FL} of the fiber layer FL may be about 40 μm to about 100 μm. In one or more embodiments, the flexural modulus of the support plate FP may be about 10 GPa to about 35 GPa.

The support plate FP may include a plurality of fiber layers FL designed to have a specific thickness according to the thickness t_{FP} of the support plate FP, thereby improving the surface quality thereof. Accordingly, the display quality of the electronic device ED (see, e.g., FIG. 1A) may be improved.

Compared to FIG. 8A, FIGS. 8C and 8D are each an enlarged cross-sectional view illustrating that a support plate FP according to one or more embodiments includes three sub-plates SFP-1, SFP-2, and SFP-3.

Referring to FIG. 8C, the support plate FP according to one or more embodiments may include a first sub-plate SFP-1 disposed adjacent to the display panel DP (see, e.g., FIG. 3A), a second sub-plate SFP-2 disposed under the first sub-plate SFP-1, and a third sub-plate SFP-3 disposed under the second sub-plate SFP-2. The support plate FP including the first to third sub-plates SFP-1, SFP-2, and SFP-3 may include a plurality of fiber layers FL having the same thickness t_{FL}. For example, the first to third sub-plates SFP-1, SFP-2, and SFP-3 may respectively include the fiber layers FL having the same thickness t_{FL}. Because the thicknesses t_{FL} of the fiber layers FL respectively included in the first to third sub-plates SFP-1, SFP-2, and SFP-3 may each independently be the same, the thicknesses of the first to third sub-plates SFP-1, SFP-2, and SFP-3 may be the same as each other.

Referring to FIG. 8D, the support plate FP may include a plurality of fiber layers FL having thicknesses different from each other. For example, the fiber layers FL included in the sub-plates SFP may respectively have thicknesses different from each other. Accordingly, the sub-plates SFP may respectively have thicknesses different from each other. In one or more embodiments, the fiber layers FL disposed in the outermost region of the support plate FP may be thinner than the fiber layers FL disposed inside the support plate FP. In the support plate FP according to one or more embodiments, two sub-plates SFP, disposed on the uppermost surface and the lowermost surface exposed to the outside, among the plurality of sub-plates SFP may be thinner than other sub-plates SFP disposed inside the support plate FP.

For example, the support plate FP may include the first to third sub-plates SFP-1, SFP-2, and SFP-3 sequentially stacked along the third direction DR3. The first sub-plate SFP-1 disposed on the uppermost side of the support plate FP may include the fiber layer FL having a first thickness t_{FL-a}, and the third sub-plate SFP-3 disposed on the lowermost side of the support plate FP may include the fiber layer FL having a third thickness t_{FL-c}. The second sub-plate SFP-2 may be disposed inside the support plate FP, and may include the fiber layer FL having a second thickness t_{FL-b}. The first thickness t_{FL-a} and the third thickness t_{FL-c} of the fiber layers FL disposed in the outermost regions of the support plate FP may have smaller thicknesses than the second thickness t_{FL-b} of the fiber layer FL disposed inside the support plate FP.

FIGS. 8E and 8F are graphs showing the lattice visibility and the physical properties of the support plate according to embodiments of the present disclosure. FIG. 8E shows the evaluation result of the physical properties and the lattice visibility versus the thickness of the fiber layer FL in a support plate FP according to embodiments of the present disclosure. In FIG. 8E, the thickness of the support plate FP is about 170 μm, and in FIG. 8F, the thickness of the support plate FP is equal to or less than about 200 μm. FIG. 8F shows the evaluation result of the physical properties and the lattice visibility versus the number of the sub-plates SFP included in the support plate FP. In FIG. 8F, the number of the sub-plates SFP is the same as the stack number of the fiber layers FL, and the stack number of the fiber layers FL is two, three, or four. In FIGS. 8E and 8F, the fiber layers FL includes woven glass fibers.

Referring to FIG. 8E, when the support plate FP according to embodiments of the present disclosure having a thickness of about 200 μm or less has fiber layers FL having a thickness of about 35 μm, about 40 μm, about 50 μm, and about 63 μm, the support plate FP shows good or suitable flexural moduli of about 20 GPa or more. However, it may be seen that when the fiber layer FL has a thickness of about 50 μm or more, the grain-direction waviness of the support plate FP may be viewed, and the lattice visibility of the support plate FP may be thus deteriorated.

Referring to FIG. 8F, it may be confirmed that when two to four sub-plates SFP, that is, two to four fiber layers FL are stacked in the support plate FP, the support plate FP shows good or suitable flexural modulus and relaxed lattice visibility. For example, it may be seen that when four fiber layers FL having a thickness of about 43 μm are stacked, the support plate FP shows excellent or suitable modulus and relaxed lattice visibility.

When the thickness of the fiber layer FL is designed to have a specific range according to the thickness of the support plate FP, and the stack number of the fiber layers FL, the thickness of the fiber layer FL, etc., are controlled or selected, the support plate FP according to one or more embodiments may show high stiffness and excellent or suitable modulus.

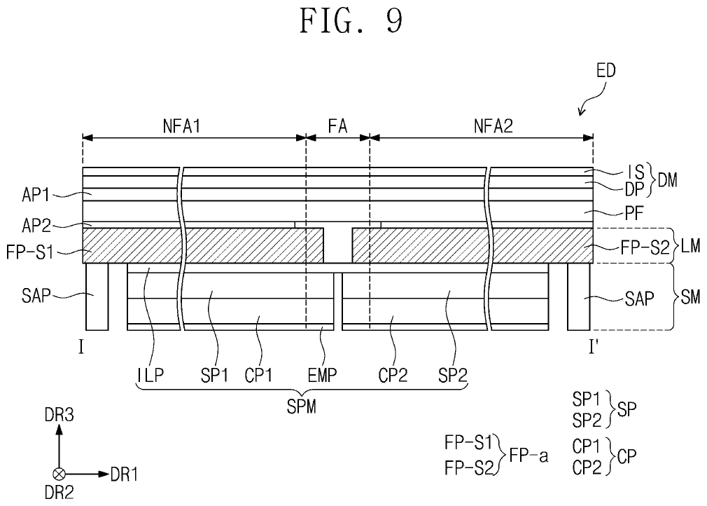

FIG. 9 is a cross-sectional view of an electronic device according to one or more embodiments of the present disclosure. Compared to FIG. 3A, FIG. 9 illustrates an electronic device having a support plate having a shape different from that in FIG. 3A, according to one or more embodiments of the present disclosure. In description of the electronic device ED according to one or more embodiments, content duplicated with those described above with reference to FIGS. 1A to 8D may not be described again, and differences may be mainly described.

Referring to FIG. 9, the electronic device ED according to one or more embodiments may include a support plate FP-a disposed under the display module DM. In one or more embodiments, the support plate FP-a may include a first plate FP-S1 and a second plate FP-S2 separated and spaced apart from (separated from) each other. The first plate FP-S1 and the second plate FP-S2 may be spaced apart (separated) in the first direction DR1 perpendicular to an extending direction of the first folding axis AX1 (see, e.g., FIG. 2).

The first plate FP-S1 may overlap the first non-folding region NFA1. At least a part of the first plate FP-S1 may not overlap the folding region FA. The second plate FP-S2 may be disposed spaced apart from (separated from) the first plate FP-S1, and may overlap the second non-folding region NFA2. At least a part of the second plate FP-S2 may not overlap the folding region FA. In one or more embodiments, the first plate FP-S1 may correspond to a first plate non-folding part NFA1-FP, and the second plate FP-S2 may correspond to a second plate non-folding part NFA2-FP (see, e.g., FIG. 5). The first plate FP-S1 and the second plate FP-S2 may each include a plurality of sub-plates SFP (see, e.g., FIG. 7). The description of the plurality of sub-plates SFP (see, e.g., FIG. 7) made above may be similarly applied.

Table 1 shows the physical properties and the surface quality of the support plate FP versus the thickness of the fiber layer FL and the stack number of the sub-plates SFP. Carbon fiber reinforced plastic (CFRP) or glass fiber reinforced plastic (GFRP) is utilized as a material of the support plate FP, and the support plate FP has a structure in which three or four sub-plates are stacked like FIGS. 8A and 8C, or a structure in which one more sub-plate is added to the support plate FP in FIG. 8A and thus five sub-plates are stacked. In Table 1, “ply” corresponds to the number of the sub-plates, and “surface quality” indicates the evaluation result of observing with naked eyes whether the grain-direction waviness is viewed on the surface of the support plate FP or not. In Table 1, “glass style” refers to IPC (Interconnecting and Packaging Electronic Circuit) standard.

Table 1 shows a flexural property result measured through a 3-point bending method utilizing a universal testing machine (UTM). Testing standard is ASTM D790. Table 1 shows the results obtained by calculating the flexural modulus, strength, and bending stiffness utilizing a slope value and a flexural load value as measured through the universal testing machine (UTM).

TABLE 1

| Stack | | | | | | | | | |
|---|---|---|---|---|---|---|---|---|---|
| condition | | GFRP | | | | | | | |
| # Number: | CFRP | #1037 | #1037 | #1067 | #1067 | #1078 | #1078 | #1086 | #3313 |
| Glass Style | 3ply | 4ply | 5ply | 3ply | 4ply | 3ply | 4ply | 3ply | 3ply |
| Fiber layer | — | 30 | 30 | 35 | 35 | 43 | 43 | 52 | 81 |
| thickness | | | | | | | | | |
| (μm) | | | | | | | | | |
| Sub-plate | 0.176 | 0.144 | 0.17 | 0.17 | 0.169 | 0.168 | 0.181 | 0.181 | 0.193 |
| thickness | | | | | | | | | |
| (mm) | | | | | | | | | |
| Slope | 0.51 | 0.17 | 0.30 | 0.27 | 0.30 | 0.306 | 0.449 | 0.391 | 0.53 |
| (N/mm) | | | | | | | | | |
| Flexural | 4.51 | 1.45 | 2.59 | 2.32 | 2.54 | 2.67 | 4.07 | 3.26 | 4.52 |
| Load (N) | | | | | | | | | |
| Flexural | 37 | 22 | 24 | 21 | 24 | 25 | 30 | 26 | 29 |
| Modulus | | | | | | | | | |
| (GPa) | | | | | | | | | |
| Strength | 137 | 65 | 84 | 75 | 83 | 89 | 117 | 93 | 114 |
| (MPa) | | | | | | | | | |
| Bending | 150 | 56 | 96 | 87 | 97 | 100 | 146 | 127 | 172 |
| Stiffness | | | | | | | | | |
| (N · mm²) | | | | | | | | | |
| Surface | strong | good or | good or | good or | good or | good or | good or | medium | strong |
| quality | | suitable | suitable | suitable | suitable | suitable | suitable | | |

Referring to Table 1, the support plates utilizing GFRP or CFRP show good or suitable physical properties. For example, the support plate utilizing GFRP as a material thereof shows a better surface quality than the support plate utilizing CFRP as a material thereof.

Accordingly, an electronic device according to one or more embodiments includes a reinforced fiber and a plate including a fiber layer having a thickness having a specific range according to the thickness of a support plate thereof, thereby being lightweight and showing improved display quality.

An electronic device according to one or more embodiments may include a support plate including a reinforced fiber and having a specific stack structure, thereby mitigating or reducing the visibility of grain-direction waviness on the surface of the support plate. Accordingly, the electronic device according to one or more embodiments may improve display quality.

In addition, the electronic device according to one or more embodiments may include the above support plate, thereby having a smaller thickness and being more lightweight while showing good or suitable flexibility and mechanical properties.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. An electronic device comprising:
a display panel comprising a folding region to fold with respect to a folding axis extending in one direction, and a non-folding region comprising a first non-folding region and a second non-folding region separated from the first non-folding region with the folding region between the first non-folding region and the second non-folding region; and
a support plate comprising a plurality of fiber layers comprising a plurality of reinforced fibers, the support plate being under the display panel,
wherein the support plate has a thickness of about 100 μm to about 300 μm, and
when the thickness of the support plate is about 100 μm to about 200 μm, each of the plurality of fiber layers has a thickness of equal to or greater than about 30 μm and less than about 50 μm, and
when the thickness of the support plate is greater than about 200 μm and equal to or smaller than about 300 μm, each of the plurality of fiber layers has a thickness of about 40 μm to about 100 μm.

2. The electronic device of claim 1, wherein each of the plurality of reinforced fibers comprises a glass fiber.

3. The electronic device of claim 2, wherein each of the plurality of fiber layers has a woven shape in which reinforced fibers of the plurality of reinforced fibers are arranged alternately.

4. The electronic device of claim 1, wherein the support plate further comprises a matrix part comprising a polymer resin, and the plurality of fiber layers are inside the matrix part.

5. The electronic device of claim 4, wherein the support plate further comprises inorganic particles dispersed in the matrix part.

6. The electronic device of claim 4, wherein the matrix part comprises at least one of an epoxy-based resin, a polyester-based resin, a polyamide-based resin, a polycarbonate-based resin, a polypropylene-based resin, a polybutylene-based resin, or a vinyl ester-based resin.

7. The electronic device of claim 1, wherein the support plate has a flexural modulus of about 10 GPa to about 35 GPa.

8. The electronic device of claim 1, wherein each of the plurality of fiber layers has the same thickness.

9. The electronic device of claim 1, wherein fiber layers of the plurality of fiber layers have thicknesses different from each other, and
fiber layers of the plurality of fiber layers on an outermost region of the support plate are thinner than fiber layers of the plurality of fiber layers inside the support plate.

10. The electronic device of claim 1, wherein the support plate comprises a plurality of sub-plates stacked in a thickness direction, and
each of the plurality of sub-plates comprises at least one of the plurality of fiber layers.

11. The electronic device of claim 10, wherein a total number of the plurality of sub-plates in the support plate is three to five.

12. The electronic device of claim 1, wherein the support plate comprises:
a folding part corresponding to the folding region, and having a plurality of openings;
a first plate non-folding part corresponding to the first non-folding region; and
a second plate non-folding part corresponding to the second non-folding region.

13. The electronic device of claim 12, wherein the plurality of openings comprises a plurality of first openings and a plurality of second openings arranged in a staggered manner in a first direction.

14. The electronic device of claim 1, wherein the support plate comprises:
a first plate overlapping the first non-folding region; and
a second plate overlapping the second non-folding region, and apart from the first plate.

15. The electronic device of claim 10, wherein the plurality of reinforced fibers are about 48 wt % to about 52 wt % with respect to a total weight of the plurality of sub-plates.

16. The electronic device of claim 1, further comprising a hard coat layer on top of and/or under the support plate.

17. The electronic device of claim 16, wherein the hard coat layer has a thickness of about 1 μm to about 20 μm.

18. An electronic device having a folding region to fold with respect to a folding axis extending in one direction, and a non-folding region adjacent to the folding region, the electronic device comprising:
a display module; and
a support plate comprising a matrix part and a plurality of fiber layers inside the matrix part, the support plate being under the display module,
wherein the support plate comprises a plurality of sub-plates stacked in a thickness direction,
each of the plurality of sub-plates comprises a fiber layer of the plurality of fiber layers having a thickness proportional to a thickness of the support plate, and
the plurality of fiber layers comprise glass fibers having a woven shape in which fibers are arranged alternately.

19. The electronic device of claim 18, wherein the support plate has a thickness of about 100 μm to about 300 μm,
when the thickness of the support plate is about 100 μm to about 200 μm, each of the plurality of fiber layers has a thickness of equal to or greater than about 30 μm and less than about 50 μm, and
when the thickness of the support plate is greater than about 200 μm and equal to or smaller than about 300 μm, each of the plurality of fiber layers has a thickness of about 40 μm to about 100 μm.

20. The electronic device of claim 18, wherein a total number of the plurality of fiber layers in the support plate is three to five.
